(19) United States
(12) Patent Application Publication
(10) Pub. No.: US 2020/0355857 A1
(43) Pub. Date: Nov. 12, 2020

(54) SINGLE CRYSTALLINE DIAMOND DEFRACTIVE OPTICAL ELEMENTS AND METHOD OF FABRICATING THE SAME

(71) Applicant: ECOLE POLYTECHNIQUE FEDERALE DE LAUSANNE, Lausanne (CH)

(72) Inventors: Niels QUACK, Yverdon (CH); Marcell KISS, Chavannes-Renens (CH); Teodoro GRAZIOSI, Renens (CH)

(21) Appl. No.: 16/642,239

(22) PCT Filed: Aug. 28, 2018
(86) PCT No.: PCT/IB2018/056547

§ 371 Date: Feb. 26, 2020

(30) Foreign Application Priority Data
Aug. 30, 2017 (IB) PCTIB2017055208

(51) Int. Cl. G02B 5/18; C30B 29/04; C30B 33/12; G02B 1/02; G02B 27/10

(52) U.S. Cl. CPC G02B 5/1857; C30B 29/04; G02B 27/1073; G02B 1/02; C30B 33/12

(57) ABSTRACT

The present invention concerns a single crystalline diamond optical element production method. The method includes the steps of: —providing a single crystalline diamond substrate or layer; —applying a mask layer to the single crystalline diamond substrate or C layer; —forming at least one or a plurality of indentations or recesses through the mask layer to expose a portion or portions of the single crystalline diamond substrate or layer, and —etching the exposed portion or portions of the single crystalline diamond substrate or layer.

### CROSS-REFERENCE TO RELATED APPLICATIONS

The present application claims priority to International Patent Application PCT/IB2017/055208 filed on Aug. 30, 2017, the entire contents thereof being herewith incorporated by reference.

### FIELD OF THE INVENTION

The present invention relates to a method for fabricating optical components in single crystalline diamond. The present invention relates to a method for fabricating optical components in single crystalline diamond exhibiting atomically smooth surfaces along well-defined crystal planes. The present invention further concerns optical diffractive components consisting solely of a single crystalline diamond part or product, including but not limited to optical gratings or beam splitters.

### BACKGROUND

With the recent availability of industrial high purity chemical vapor deposition (CVD) single crystalline diamond, applications that take advantage of its unique optical and mechanical properties have been widely reported.

Mechanical structures such as nanomechanical resonators, nanowire tips and cantilevers have been demonstrated.

In the field of optics, micro-lenses, gratings and microcavities are applications where single crystalline diamond is an ideal material.

The ability to microstructure crystalline bulk material to reveal the crystalline planes is a known phenomenon in microfabrication. Grating structures of triangular or rectangular profile have been fabricated in silicon using a variety of wet etchants (KOH, TMAH, etc.), also exploiting the effect of having an etchant selective to certain crystalline planes. If the substrate is miscut, i.e. the substrate surface is purposely aligned in a well-defined angle offset with respect to the principal crystal planes, it is possible to fabricate blazed (or asymmetric or echelette) gratings. The grating can also be used in combination with a prism, as an immersion element or in conjunction with MEMS structures in order to achieve tunability.

It is also possible to utilise anisotropic etching methods to create optical components such as diffraction gratings with vertical or close-to-vertical sidewalls. Such gratings have previously been demonstrated in single crystalline diamond. Similarly, it has been demonstrated, that structuring by femtosecond or other lasers can be used to create vertical patterns in single crystal diamond.

Yet another fabrication method for creating grating patterns has been demonstrated in single crystalline diamond using ion implantation.

However, hitherto demonstrated elements produced by the methods cited above are limited in the surface quality and in their control of the sidewall or grating angle.

### SUMMARY OF THE INVENTION

It is therefore one aspect of the present disclosure to provide a single crystalline diamond diffractive optical element fabrication method that overcomes the above challenges. The present invention thus relates to a method according to claim 1.

The method preferably includes the steps of:
providing a single crystalline diamond substrate or layer;
applying a mask layer to the single crystalline diamond substrate or layer;
forming at least one or a plurality of indentations or recesses through the mask layer to expose a portion or portions of the single crystalline diamond substrate or layer; and
etching the exposed portion or portions of the single crystalline diamond substrate or layer.

This method advantageously allows optical component such as optical diffraction gratings with grooves defined by crystallographic planes (for example, V-grooves or rectangular shaped grooves) to be produced in single crystalline diamond. The method advantageously provides optical structures having precisely defined sidewall side wall angles and highly or atomically smooth optical surfaces.

It is another aspect of the present disclosure to provide a single or mono crystalline diamond diffractive optical component or diffraction grating or product produced by this method.

It is yet another aspect of the present disclosure to provide a single crystalline diamond optical element, wherein the optical element is a free-standing reactive-ion-etched synthetic single crystalline diamond optical element.

The above and other objects, features and advantages of the present invention and the manner of realizing them will become more apparent, and the invention itself will best be understood from a study of the following description with reference to the attached drawings showing some preferred embodiments of the invention.

### A BRIEF DESCRIPTION OF THE DRAWINGS

The above object, features and other advantages of the present invention will be best understood from the following detailed description in conjunction with the accompanying drawings, in which:

FIG. 1A shows an embodiment of an optical diffraction grating exhibiting, for example, V-grooves on the surface of a single crystal diamond substrate or layer.

FIG. 1B shows an exemplary a single crystalline diamond substrate or layer used in the method of the present disclosure. The indicated dimensions values are non-limiting exemplary values.

FIG. 2 shows an example of a fabricated triangular or V-groove grating in single crystalline diamond obtained with the method of the present disclosure. The grating exhibits V-grooves with for example a characteristic angle α of 54.7°, or close to or about 54.7° with respect to the surface. Crystallographic planes are highlighted by stripes added to the image.

FIG. 3 shows an exemplary single crystalline diamond diffraction grating fabrication method as well as exemplary materials that may be used in this method.

FIG. 4 shows a photograph of the diamond grating showing the diffraction grating effect. The photograph is of a single crystal diamond plate with three grating regions of different density as indicated in FIG. 4. The incident white light is separated in transmission, causing a color gradient.

FIG. 5 shows an experimental optical diffraction measurement of a diffraction grating of the present disclosure. The measured spectral response of a single crystal diamond grating (100 g/mm) of the present disclosure in transmission as a function of angle is shown.

FIG. 6 shows possible steps of a variant of the fabrication process to obtain blazed (or asymmetric or echelette) gratings as well as well as exemplary materials that may be used. The angle α can be, for example, 54.7° or about 54.7° but is not limited to this angle.

FIG. 7 shows the arrangement of the single crystal diamond substrate crystal orientation to obtain blazed gratings. The angle α can be, for example, 54.7° or about 54.7° but is not limited to this angle.

FIG. 8(a) shows a SEM image of an optical grating comprising V-shaped grooves produced according to the method of the present disclosure; FIG. 8(b) shows an AFM surface profile; FIG. 8(c) shows an extracted profile across a groove in a <110> direction; FIG. 8(d) shows a SEM image of an optical grating comprising rectangular grooves with vertical sidewalls produced according to the method of the present disclosure; FIG. 8(e) shows a vertical sidewall AFM profile; and FIG. 8(e) shows an extracted profile across a groove in a <010> direction.

Herein, identical reference numerals are used, where possible, to designate identical elements that are common to the Figures.

### DETAILED DESCRIPTION OF SEVERAL EMBODIMENTS

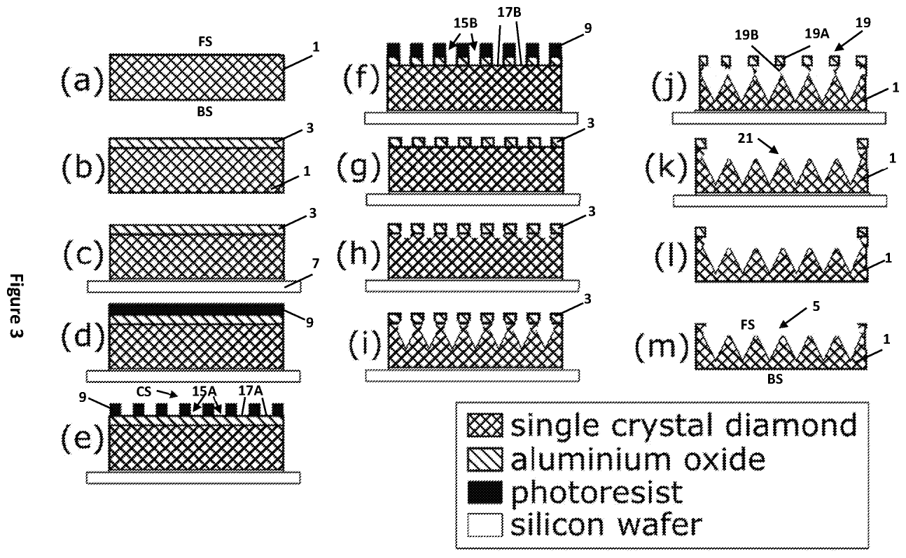

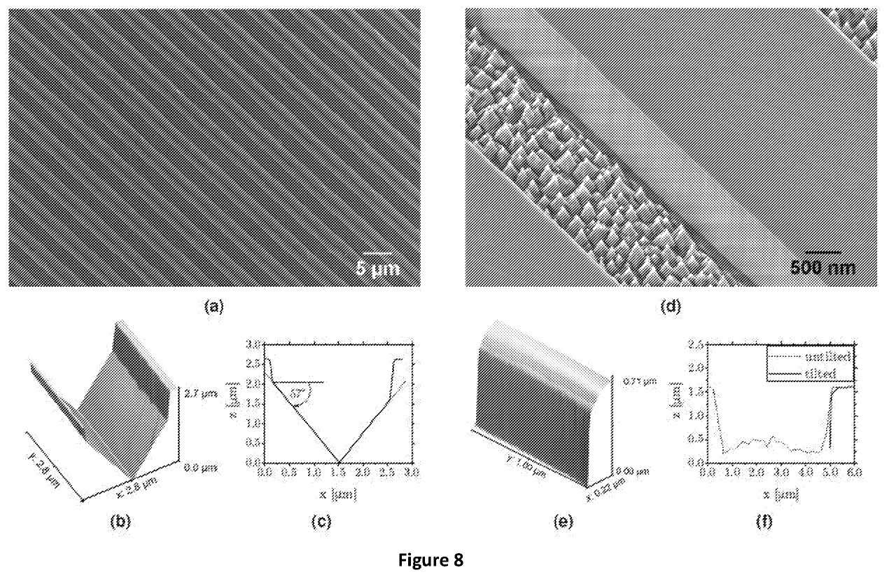

FIG. 3 shows an exemplary embodiment of a single crystalline diamond production method for producing optical elements or components. FIGS. 2 and 8 show images of exemplary diamond optical components, for example, diamond gratings produced by this method.

The method of the present disclosure is, for example, for fabricating optical components or elements in single crystalline diamond.

The process uses single or mono crystal or crystalline diamond substrates or layers 1.

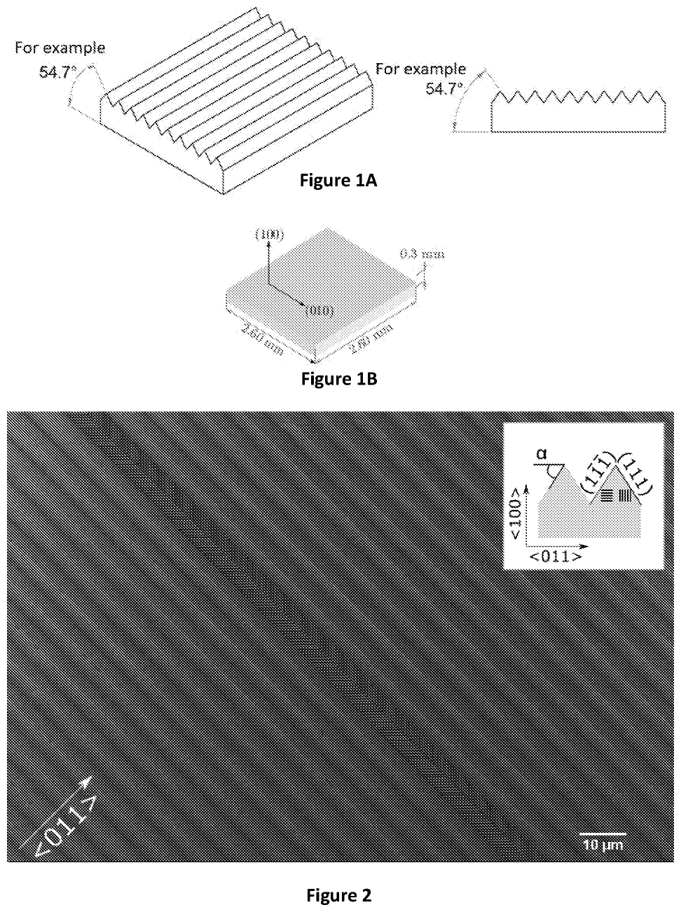

The single crystalline diamond substrates or layers can, for example, be of dimensions 2.6 mm (length (x-direction))×2.6 mm (width (y-direction))×0.3 mm (thickness t (z-direction)) as shown, for example, in FIG. 1B. However, the method of the present disclosure is not limited to such dimensions and the single crystalline diamond substrate or layer 1 can be larger or shorter in length and width and can also have a larger or smaller thickness.

The optical diamond components comprising grooves of height between 1 μm and 10 μm can be for example produced.

The single crystalline diamond substrate or layer 1 is preferably non-natural or synthetic single crystalline diamond, for example, chemical vapor deposition CVD single crystalline diamond or synthetic diamond by HPHT (high pressure high temperature) synthesis.

The single crystalline diamond substrate or layer 1 can be, for example, a (100) orientation (Miller indices) single crystalline diamond substrate or layer 1, an example of which is shown in FIG. 1B.

A quasi-anisotropic or “crystalline” reactive ion etching process can be used to selectively etch crystalline planes of the diamond substrate or layer 1.

The different etch rates for the planes can produce a triangular microstructure (as for example seen in FIG. 2) revealing the crystalline planes of the bulk material.

Optical structures such as grating patterns can be defined using photolithography and hard mask etching. FIG. 1A shows a conceptual drawing of an exemplary diffraction grating produced by the method of the present disclosure, and FIG. 2 shows an image of an actual fabricated grating, with the crystalline planes (Miller indices) indicated in the inset.

The method includes providing the single crystalline diamond substrate or layer 1. A mask layer 3 is applied or deposited on the single crystalline diamond substrate or layer 1. At least one or a plurality of indentations, recesses or depressions 15B are formed through the mask layer 3. This exposes at least one portion or a plurality of portions or surfaces 17B of the single crystalline diamond substrate or layer 1 which can then undergo etching to define the optical structures in the single crystalline diamond substrate or layer 1.

In the exemplary embodiment of the method shown in FIG. 3 it is not necessary for all the all the steps to be carried out and the steps may be carried out in an order different to that shown in the detailed process flow shown in FIG. 3. Moreover, the material indicated in FIG. 3 concerns exemplary materials and the method is not limited to the use of these materials.

In this exemplary process, cleaning of the (100) single crystalline diamond substrate 1, with dimensions about 2.6 mm×2.6 mm×0.3 mm, using for example a cleaning solution such as a Piranha solution (H₂SO₄(96%):H₂₂(30%) (3:1)) (step a) may firstly be carried out. Cleaning can alternatively or additionally be carried out using acetone and/or IPA.

A thin (for example, 100 nm) hardmask layer 3 is deposited (for example, silicon oxide, or silicon nitride, or preferably aluminium oxide) on a front side FS of the substrate 1 using for example sputtering (step b). For the aluminium oxide, the deposition conditions are for example 700 W RF power, 50 sccm Ar flow. The thickness of the hardmask layer 3 depends on the desired depth of the depressions or grooves 5, which is a function of the optical element or grating pitch.

The mask layer 3 comprises or consists solely of a material that etches slower than single crystalline diamond exposed to etching.

As mentioned the mask layer 3 may comprise or consist solely of silicon oxide, or silicon nitride, or aluminium oxide.

The mask layer 3 may comprises or consists solely of Al, or Si, or Au, or Ti, or Si₃N₄, or Ni, or a Ni—Ti alloy, or W; or Ag, or Cu, or Fe, or Cr, or Co, or Ga, or Ge, or In, or Mo, or NiFe, or NiCr, or Nb, or Pd, or Pt, or Si, or Sn, or Ta, or Y; or MgO, or Indium Tin Oxide (ITO, In₂O₃—SnO₂), or Titanium Oxide TiO₂, or Ti₂O₃, or Ti₃O₅, or ZrO₂, or HfO₂, or La₂O₃, or Y₂O₃ or SiC; or any combination of the above.

The mask layer 3 preferably has a thickness of between 10 nm and 1 μm.

The substrate 1 is attached on a support member 7 such as for example a silicon handling wafer via for example gluing with an adhesive or mounting wax, for example, Quickstick 135 (step c). This can be, for example, optionally followed by an Hexamethyldisilazane (HMDS) vapor deposition at 130° C., in order to improve a subsequently deposited photoresist adhesion. It should be noted that step c may however be carried out earlier or later in the process. The step of attaching the single crystalline diamond substrate or layer 1 to a support is preferably carried out prior to forming the indentations 15B in the mask layer 3 and/or prior to lithographic definition of the structures in a photoresist layer 9.

A profile forming layer 9 is provided on the mask layer 3 for forming the at least one indentation or the plurality of indentations 15B in the mask layer 3 (step d).

At least one or a plurality of indentations or recesses 15A are formed through the profile forming layer 9 to expose a portion or portions 17A of the mask layer 3 (step e).

The profile forming layer 9 may comprises or consists solely of a photoresist. The at least one or the plurality of indentations or recesses 15A are formed through the profile forming layer 9 to expose the at least one portion or portions 17A of the mask layer 3. This is done by applying a photoresist developer to at least one or a plurality of lithographically exposed indentations or recesses in the profile forming layer 9.

A photoresist 9, for example, a layer 9 of about 0.4 μm thick layer of AZ ECI 3007 photoresist is deposited for instance by spin coating at for example 5000 rpm, followed by a softbake at for example 100° C. (step d).

A substantial edge-bead (not-illustrated) may form when the substrate 1 is of rectangular shape and a step of photoresist can form between the handling substrate 7 and the frontside FS of the diamond substrate 1. Edge beads also form on substrates of other shapes such as circular shapes, and also form on larger substrates. It is preferably that they be removed, in order to obtain good lithography resolution (minimizing distance of mask to photoresist).

In order to remove this edge-bead, an (optical or electron beam) exposure (for example, 170 mJ/cm²) of the photoresist 9 is done on the edge-bead affected region (for example, from the substrate 1 edge to a predefined inner distance from the edge towards the centre of the substrate 1, for example about 0.3 mm inside the substrate), followed by a standard development in an AZ 726 MIF developer for example, for 27 seconds. This removal is preferable for optical lithography but not mandatory.

An (optical or electron beam) exposure (for example, 85 mJ/cm²) is performed on the central region CS of the substrate 1, with the pattern of, or corresponding to, the parts to be fabricated or the structure to be formed in the diamond layer or substrate 1 (for example, patterns in the <110> or <100> direction), followed by a development in developer AZ 726 MIF for, for example, 27 seconds (step e) to produce the structure, indentations or recesses 15A.

Exposure of the photoresist 9 is carried out to lithographically define a desired structure, indentations or recesses in the photoresist 9 that will be transferred or produce a corresponding structure in the diamond layer or substrate 1 after etching has been carried out.

The structure, for example, grooves or elongated depressions are lithographically defined and aligned in a predetermined direction of the single crystalline diamond substrate or layer 1, for example, are aligned in the <110> or <100> direction of the single crystalline diamond substrate or layer 1.

Alignment in the <110> direction of the single crystalline diamond substrate or layer 1 permits a V-shaped structure such as V-shaped trenches or grooves to be produced in the single crystalline diamond substrate or layer 1. The formation of V-shaped grooves are due to the revealing of the (111) crystallographic planes that exhibit a lower etch rate compared to the (110) and (100) planes. The etching slows down on these (111) planes, leading to the V-shape. The angle of the trench to the surface will approximate the angle between the crystalline planes (54.7°), the exact value depending on the ratio of the etch rates.

Alignment in the <100> direction of the single crystalline diamond substrate or layer 1 permits a U-shaped or rectangular shaped structure such as trenches or grooves to be produced in the single crystalline diamond substrate or layer 1. The formation of U-shaped grooves is due to the revealing of the (100) crystallographic planes that exhibit a lower etch rate compared to the (110) planes, resulting in the etch slowing on the (100) planes, leading to the U-shape. The angle of the trench to the surface will approximate the angle between the crystalline planes (90°), the exact value depending on the ratio of the etch rates.

Alignment of the patterns to the crystalline directions is done by aligning the patterns to the edges of the diamond substrate which has a known crystalline direction. When performing, for example, an optical exposure, the substrate is rotated with respect to the indentations on the mask, until the direction of indentations (composed for example of elongated rectangles) correspond to the desired crystalline direction, which direction is inferred from the known crystalline direction of the substrate edge. The crystal orientation of the diamond substrate is known. The crystal orientation can, for example, be determined by X-Ray Diffractometry during the substrate preparation process. The diamond substrates (plates) have thus a well-defined crystal orientation with respect to the edges of the plate and the surface of the plate.

During, for example, an electron beam exposure, the exposed patterns are rotated for example by software. As an example, a substrate with (100) surface and <100> edges will produce V-grooves, if the indentations on the mask form 45° angle with the substrate edge, since the indentations are now aligned to the substrate's<110> crystalline direction.

The mask layer 3, for example, aluminium oxide is etched. Etching is carried out on the exposed the portions 17A of the mask layer 3 to form a plurality of indentations or recesses 15B through the mask layer 3 to expose a portion or portions 17B of the single crystalline diamond substrate or layer 1.

Etching can be carried out for example in a deep reactive ion etcher using chlorine chemistry (STS Multiplex), or for example in a Cl₂/BC₃l/Ar based plasma for a duration of for example 3 minutes (step f).

The photoresist 9 can be stripped from the structure, for example using acetone (step g).

The single crystalline diamond substrate (that is the exposed a portion or portions 17B of the single crystalline diamond substrate or layer 1) is etched in an O₂ plasma (produced for example at 2000 W ICP power, 0 W bias power, 100 sccm O₂ flow, 15 mTorr chamber pressure). Etching of the single crystalline diamond substrate or layer 1 can be carried out using only an O₂ plasma etching.

Chemical plasma etching is carried out.

Etching can be carried out using deep reactive ion etching (SPTS APS) with an Oxygen plasma utilizing high ICP power (for example, 2000W ICP) and no bias power.

Alternatively, chemical plasma etching can be carried out in a plasma produced using one of the following gases: H₂, CH₄, fluorine gases (SF₆, CₓF_{y}), chlorine gases (BCl₃, Cl₂).

The mask layer 3 preferably comprises or consists solely of a material that etches slower than single crystalline diamond exposed to an oxygen-based plasma etch or exposed to a chemical plasma etch involving one of the above-mentioned gases.

Alternatively, the etching of the single crystalline diamond substrate or layer (1) can be carried out at an elevated temperature in an oxygen rich environment and as a non-plasma etch. For example, etching can be carried out by heating the single crystalline diamond substrate 1 to a high temperature (for example, 600 to 1200° C.) in an oxygen ambient (step h).

The RIE machine used for the diamond substrate or layer 1 etch for the optical components shown in FIGS. 2 and 8 was a SPTS APS Dielectric etcher.

Plasma etching of the single crystalline diamond substrate or layer 1 is carried out ion acceleration-free. That is, using the plasma etch (for example an oxygen-based plasma etch), no acceleration (or low acceleration) of the plasma created ions is carried out to avoid or minimize physical etching of the exposed single crystalline diamond substrate or layer 1 coming from ion impact or bombardment thereon. The single crystalline diamond substrate or layer 1 is etched principally or solely by chemical reaction.

An ion impact-free or bombardment-free physical etching is preferably preformed, or the acceleration level of the plasma created ions is such that crystallographic etching or anisotropic etching along one or more crystal planes is favorized or dominant.

Etching time was, for example, 70 minutes for the optical grating shown in FIG. 8(a) and 35 minutes for the optical grating shown in FIG. 8(d).

For the structure or grooves lithographically defined in the <110> direction, initially the etch proceeds mainly in the <100> direction, for example at an etch rate is about 6 nm/min. Afterwards, the etch front encounters the <111> planes and etching slows down (step i). Crystallographic etching or anisotropic etching along the crystal plane occurs. The etching is continued until each structure or groove becomes triangular or V-shaped (step j) or until the desired groove depth is reached (in this case no mechanical removal of the top diamond part 19B is required).

The etch can be timed so that either the top diamond part 19B (and any mask layer 19A attached thereto) detaches completely or that only a small connecting region remains, which can be mechanically cleaved (for example, by using adhesive tape, a PDMS stamp or similar), thereby removing the top diamond part (step k).

The removal of the remaining top structures can also be performed by similar mechanical means, such as brushing, or by blowing pressurized air (or an inert gas or mixture of gases).

FIG. 8(a) shows an image of a fabricated optical grating having V-shaped grooves. The gratings have a pitch of 5 μm. The asymmetry of the groove shape etch seen in FIG. 8(c) is due to a misalignment of the grating to the <110> direction resulting in an under-etch of the mask. The angle measured is (about) 57°. The grove sidewalls are smooth and have a roughness Rₐ of 5 nm (measured via AFM).

For the structure or grooves lithographically defined in the <100> direction, the etch mainly proceeds in the <100> direction, resulting in (substantially) rectangular structures or grooves (as can for example be seen in FIGS. 8(d) to 8(f)). The etching is continued until the desired etch depth is reached.

FIG. 8(d) shows an image of a fabricated optical grating having rectangular-shaped grooves. The gratings have a pitch of 4 μm, a depth of 1.37 μm and a (substantially) vertical sidewall with an angle of (about) 87°. The sidewalls are very smooth and have a measured roughness Rₐ less than 5 nm. The roughening on the floor of the rectangular structure is due to an insufficient over-etch of the mask layer resulting in micro-masking during the etch process.

The method of the present disclosure can advantageously provide optical structures having precisely defined sidewall side wall angles and atomically smooth optical surfaces or side walls.

The chip or resulting single crystalline diamond optical component or element can be removed from the carrier wafer 7 by heating on a hotplate (step 1).

The QuickStick residues can be cleaned or removed using acetone.

The mask layer or aluminium oxide can be stripped in a concentrated hydrofluoric acid or an HF (50%) bath (step m).

Both sides of the resulting structure can be O₂ plasma cleaned, for example, for 5 minutes to remove all remaining residue.

The <110> or v-shaped gratings have an angle α where 50°≤α≤65° or 54.7°≤α≤57°, for example α=54.7° in FIG. 2 and α=57 in FIG. 8(a). The <100> or rectangular shaped gratings have an angle α where 85°≤α≤95°, for example α=87 in FIG. 8(d). Their density is limited only by lithography resolution. For finer pitch gratings, e-beam lithography can be utilised.

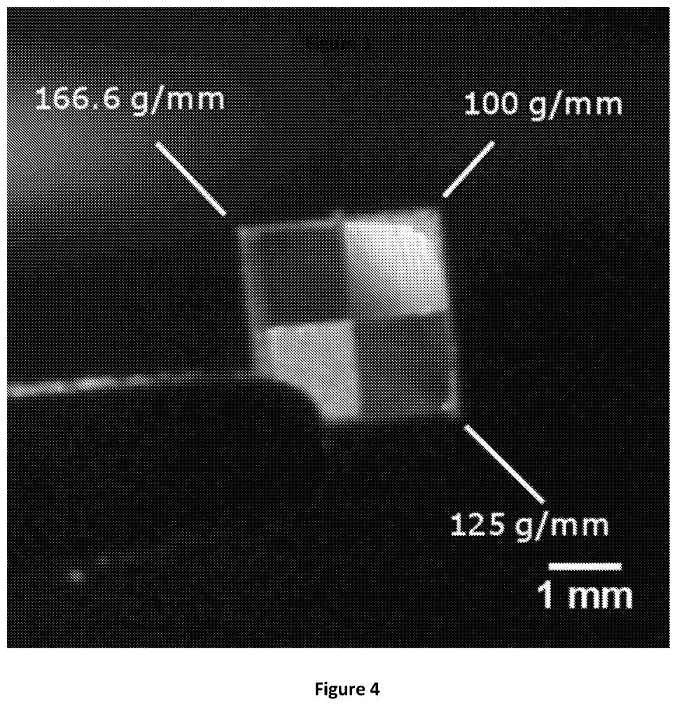

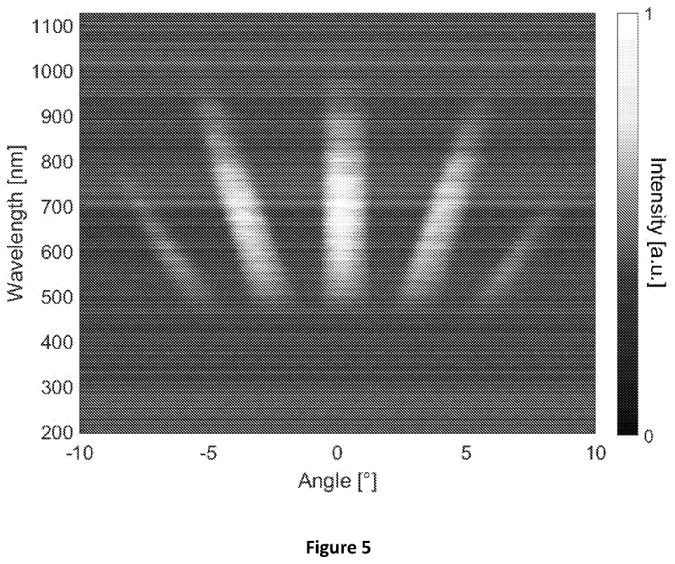

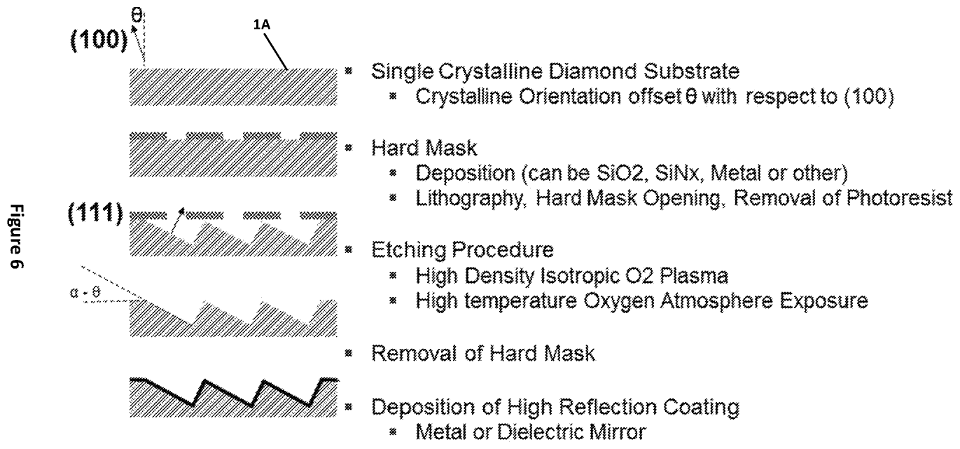

Preliminary characterisation of the gratings in transmission showing the transmitted diffracted orders in function angle and wavelength were carried out. FIG. 4 shows a photograph showing the decomposition of a white light source into its spectral components by the grating of FIG. 2. FIG. 5 shows an experimental measurement result of the spectral response of a fabricated single crystal diamond grating in transmission as a function of angle.

If the grating is intended to be used in reflection, a reflective metal layer can be deposited on the front side FS (for example, aluminium, silver, or gold metal layers) to improve reflection.

An anti-reflective coating can be applied to both the front FS and backsides BS to reduce reflection in transmission mode.

The etching process can also be terminated at step h producing gratings of trapezoidal profile, which can be of use as beam splitter elements with splitting ratios defined by the etch profile.

To the inventor's knowledge, this is the first time that such gratings are reported in single crystalline diamond.

The disclosed method has potential applications in creating optical components that were previously unavailable using gratings fabricated from conventional materials.

The following are possible avenues to exploit one of diamond's remarkable material properties, in conjunction with the realized optical properties:
Gratings for high power laser applications (high thermal conductivity)
   Laser windows, beam splitters, tunable laser gratings
Broadband spectrometer gratings (broadband transparency)
Gratings for corrosive environments (chemical inertness)
Gratings for harsh environments (mechanical hardness)

In addition to fabrication of a symmetric optical grating, blazed (or asymmetric or echelette) gratings can be fabricated by applying the disclosed fabrication process to a single crystalline diamond substrate 1A where the surface of the substrate or layer is cut or aligned in a specific and well-defined angle theta (θ) with respect to a (100) diamond crystal plane.

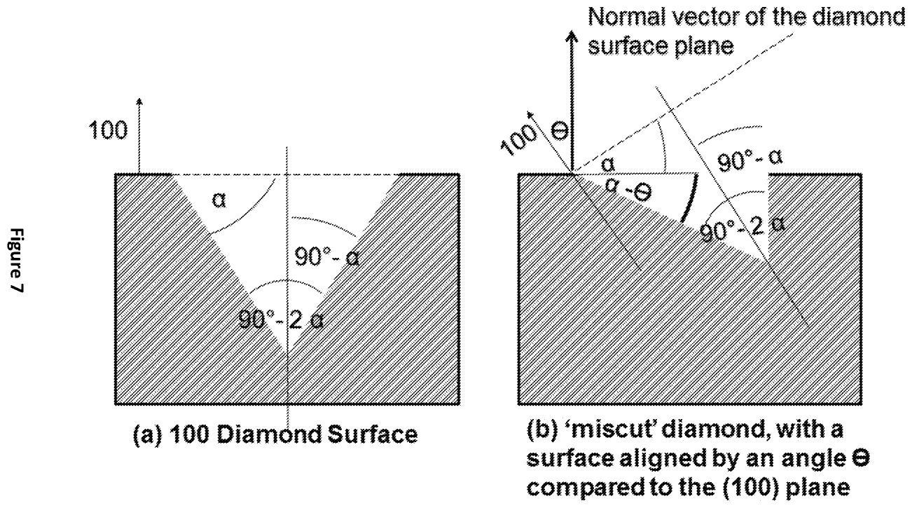

A simplified outline of the fabrication process is shown in FIG. 6. Let alpha (a) denote the groove angle attained in a non-miscut substrate. The etching procedure reveals the quasi-(111) planes, which in the case of a miscut substrate are aligned in an angle of (alpha minus theta) or (alpha plus theta) respectively with regards to the substrate surface. The V-groove angle between the two quasi-(111) planes remains the same (180°-2*alpha). The angle configuration for a miscut substrate is shown in FIG. 6.

The provided single crystalline diamond substrate or layer 1 is thus a miscut single crystalline diamond substrate or layer 1A comprising a surface of the single crystalline diamond substrate or layer defining a predetermined angle θ with respect to a crystal direction of the crystalline diamond substrate or layer 1, for example, with respect to a <100> direction of the crystalline diamond substrate or layer 1 to produce an asymmetric optical structure or a blazed optical grating.

The single crystalline diamond optical element or the optical structure or the triangular or rectangular groove structure produced by the disclosed method is for example an optical grating or beam splitter element. The optical grating or beam splitter element advantageously comprise atomically smooth optical surfaces.

The present disclosure also concerns a single crystalline diamond optical element produced according to the disclosed method. The single crystalline diamond optical element is for example a grating or beam splitter element. single crystalline diamond optical element may include an anti-reflection coating or a reflective coating. The optical element may comprise atomically smooth optical surfaces.

The optical element may include an etched grating optical surface defining an angle α with a planar surface of the single crystalline diamond substrate or layer, where 50°≤α≤65° or 54.7°≤α≤57° or where 85°≤α≤95°, or α=87°.

The present disclosure further concerns a single crystalline diamond optical element that is a free-standing reactive-ion-etched synthetic single crystalline diamond optical element. This single crystalline diamond optical element may include at least one or a plurality of reactive-ion-etched walls defining triangular or rectangular grooves. The single crystalline diamond optical element may consist solely of or comprise a free-standing reactive-ion-etched synthetic single crystalline diamond substrate or layer, and at least one or a plurality of reactive-ion-etched walls defining a grating surface. The at least one or the plurality of reactive-ion-etched walls can include at least one or a plurality of external sidewalls defining an outer boundary of the diamond part or product. The at least one or the plurality of reactive-ion-etched walls can be oxygen plasma etched walls. The at least one or the plurality of reactive-ion-etched walls can be oxygen plasma etched or walls etched by chemical reaction. The at least one or the plurality of reactive-ion-etched walls may comprise an atomically smooth surface.

The at least one or the plurality of reactive-ion-etched walls have a RMS roughness of 5 nm or less than 5 nm, or 1 nm, or less than 1 nm. The single crystalline diamond optical element can include an etched grating optical surface defining an angle α with a planar surface of the single crystalline diamond substrate or layer, where 50°≤α≤65° or 54.7°≤α≤57°; or where 85°≤α≤95°, or α=87. The synthetic single crystalline diamond is a chemical vapor deposition (CVD) or high pressure high temperature (HPHT) single crystalline diamond.

The present disclosure further concerns a single crystalline diamond optical element, wherein the single crystalline diamond optical element is obtained according to a process comprising the following steps:
providing a single crystalline diamond substrate or layer (1);
applying a mask layer (3) to the single crystalline diamond substrate or layer (1);
forming at least one or a plurality of indentations or recesses (15B) through the mask layer (3) to expose a portion or portions (17B) of the single crystalline diamond substrate or layer (1); and
reactive ion etching the exposed portion or portions (17B) of the single crystalline diamond substrate or layer (1).

While the invention has been disclosed with reference to certain preferred embodiments, numerous modifications, alterations, and changes to the described embodiments, and equivalents thereof, are possible without departing from the sphere and scope of the invention.

The features of any one of the described embodiments may be included in any other of the described embodiments.

The methods steps are not necessary carried out in the exact order presented above and can be carried out in a different order.

Accordingly, it is intended that the invention not be limited to the described embodiments, and be given the broadest reasonable interpretation in accordance with the language of the appended claims.

### REFERENCES

Ge J. . . . Bally J. Silicon immersion gratings and their spectroscopic applications (2012). Proc. SPIE 8450, Modern Technologies in Space-and Ground-based Telescopes and Instrumentation II, 84502U doi:10.1117/12.925803.
Forsberg, P., & Karlsson, M. (2013). High aspect ratio optical gratings in diamond. Diamond and Related Materials, 34, 19-24. https://doi.org/10.1016/j.diamond.2013.01.009
Frühauf, J. and Kronert, S., Wet etching of silicon gratings with triangular profiles, Microsystem Technologies, 2005, vol 11, no 12, pp1287-1291, https://link.springer.com/article/10.1007/s00542-005-0612-7
Fu, J., Wang F., Zhu, T., Wang, W., Uu, Z., U, F., . . . Hou, X. (2017). Single crystal diamond cantilever for micro-electromechanical systems. Diamond and Related Materials, 73, 267-272. https://doi.org/10.1016/i.diamond.2016.10.011
Fujii Y., Aoyama K., Minowa J-I., (1980) Optical Demultiplexer Using a Silicon Echelette Grating. IEEE Journal of Quantum Electronics, QE-16(2)
Hausmann, B. J. M., Khan, M., Zhang, Y., Babinec, T. M., Martinick, K., McCutcheon, M., . . . Lončar, M. (2010). Fabrication of diamond nanowires for quantum information processing applications.
Diamond and Related Materials, 19(5-6), 621-629. https://doi.org/10.1016/j.diamond.2010.01.011 Khanaliloo, B., Mitchell, M., Hryciw, A. C., & Barclay, P. E. (2015). High-Q/V Monolithic Diamond
Microdisks Fabricated with Quasi-isotropic Etching. Nano Letters, 15(8), 5131-5136. https://doi.org/10.1021/acs.nanolett.5b01346
Lee, C. L, Gu, E., Dawson, M. D., Friel, I., & Scarsbrook, G. A. (2008). Etching and micro-optics fabrication in diamond using chlorine-based inductively-coupled plasma. Diamond and Related Materials, 17(7-10), 1292-1296. https://doi.org/10.1016/j.diamond.2008.01.011
Lee C. L., . . . Murphy H., Fabrication and characterization of diamond micro-optics, Diamond and Related Materials, Volume 15, Issue 4, 2006, Pages 725-728, http://dx.doi.org/10.1016/j.diamond.2005.09.033.
Liu, H., Reilly, S., Herrnsdorf, J., Xie, E., Savitski, V. G., Kemp, A. J., . . . Dawson, M. D. (2016).
Large radius of curvature micro-lenses on single crystal diamond for application in monolithic diamond Raman lasers. Diamond and Related Materials, 65, 37-41. https://doi.org/10.1016/j.diamond.2016.01.016
Makita M., . . . David C. (2017), Fabrication of diamond diffraction gratings for experiments with intense hard x-rays, Microelectronic Engineering, 176, 75-78, http://dx.doi.org/10.1016/j.mee.2017.02.002
Mar D. J., Marsh P. J, Deen C. P., Ling H., Choo H., and Jaffe D. T. (2009), Micromachined silicon grisms for infrared optics, Appl. Opt. 48, 1016-1029
Nie Q., Wen Z., Huang J. (2015) A high-performance scanning grating based on tilted (111) silicon wafer for near infrared micro spectrometer application. Microsyst Technol 21:1749-1755 https://doi.org/10.1007/s00542-014-2354-x
Polikarpov, M., Polikarpov, V., Snigireva, I., & Snigirev, A. (2016). Diamond X-ray Refractive Lenses with High Acceptance. Physics Procedia, 84, 213-220. https://doi.org/10.1016/j.phpro.2016.11.037
Schaich T. J., . . . Spaaij P. G., (2005) High NA Diamond Lenses for Near-Field Optical Storage, International Symposium on Optical Memory and Optical Data Storage, OSA Technical Digest Series
Stepanov, A. L et al., (2017) A diffraction grating created in diamond substrate by boron ion implantation, Technical Physics Letters, 43, 104-106, https://doi.org/10.1134/S1063785017010266
Tao, Y., Boss, J. M., Moores, B. A., & Degen, C. L (2014). Single-crystal diamond nanomechanical resonators with quality factors exceeding one million. Nature Communications, 5. https://doi.org/10.1038/ncomms4638
Tao, Y., & Degen, C. L. (2015). Single-Crystal Diamond Nanowire Tips for Ultrasensitive Force Microscopy. Nano Letters, 15(12), 7893-7897. https://doi.org/10.1021/acs.nanolett.5b02885
Tsang, W-T., Wang S. (1975). Preferentially etched diffraction gratings in silicon Journal of Applied Physics 46:5, 2163-2166. http://dx.doi.org/10.1063/1.321859
E. Woerner, C. Wild, W. Mueller-Sebert, P. Koidl, CVD-diamond optical lenses, Diamond and Related Materials, Volume 10, Issue 3, 2001, Pages 557-560, ISSN 0925-9635, http://dx.doi.org/10.1016/SO925-9635(00)00393-9.
Zhu, T.-F., Fu, J., Wang, W., Wen, F., Zhang, J., Bu, R., . . . Wang, H.-X. (2017). Fabrication of diamond microlenses by chemical reflow method. Optics Express, 25(2), 1185. https://doi.org/10.1364/OE.25.001185

1. Single crystalline diamond optical element production method including the steps of:
providing a single crystalline diamond substrate or layer;
applying a mask layer to the single crystalline diamond substrate or layer;
forming at least one or a plurality of indentations or recesses through the mask layer to expose a portion or portions of the single crystalline diamond substrate or layer; and
etching the exposed portion or portions of the single crystalline diamond substrate or layer.

2. Method according to claim 1, wherein the etching of the exposed portion or portions of the single crystalline diamond substrate or layer is carried out using an oxygen-based plasma etch; or wherein the etching of the exposed portion or portions of the single crystalline diamond substrate or layer is carried out at an elevated temperature in an oxygen rich environment and is a non-plasma etch.

3. Method according to claim 1, wherein the etching of the exposed portion or portions of the single crystalline diamond substrate or layer is carried out using an oxygen-based plasma etch, and without physical etching via acceleration of plasma created ions against the exposed portion or portions of the single crystalline diamond substrate or layer or at an acceleration level of the plasma created ions allowing crystallographic etching or anisotropic etching along one or more crystal planes to occur.

4. Method according to the previous claim 1, wherein the etching of the exposed portion or portions of the single crystalline diamond substrate or layer is carried out using only an O₂ plasma etching.

5. (canceled)

6. Method according to claim 1, wherein the etching is carried out to etch in the <100> crystal direction of the single crystal diamond substrate or layer to reveal at least one crystal plane, and the at least one revealed crystalline plane or surface of the plane of the single crystal diamond substrate or layer is etched to produce a triangular groove structure in the single crystalline diamond substrate or layer.

7. Method according to the claim 6, wherein the etching is carried out to let the etch front encounter a (111) plane of the single crystalline diamond substrate or layer and continued to produce the triangular groove structure in the the single crystalline diamond substrate or layer.

8. Method according to claim 1, wherein the etching is carried out to etch in the crystal direction of the single crystal diamond substrate or layer to produce a rectangular groove structure in the single crystalline diamond substrate or layer.

9. Method according to claim 8, wherein the etching is carried out to let the etch front encounter a plane of the single crystalline diamond substrate or layer and continued to produce the rectangular groove structure in the the single crystalline diamond substrate or layer.

10. Method according to claim 6, further including the step of removing an upper section comprising a top diamond part and the mask layer material to expose a triangular or rectangular grooved surface.

11. (canceled)

12. Method according to claim 1, wherein the mask layer comprises or consists solely of a material that etches slower than single crystalline diamond exposed to an oxygen-based plasma etch.

13.-16. (canceled)

17. Method according to claim 1, wherein the provided single crystalline diamond substrate or layer is a miscut single crystalline diamond substrate or layer comprising a surface of the single crystalline diamond substrate or layer defining a predetermined angle with respect to a direction of the crystalline diamond substrate or layer for producing an asymmetric optical structure or a blazed optical grating.

18. Method according to claim 1, further including the step of providing a profile forming layer on the mask layer for forming the at least one indentation or the plurality of indentations in the mask layer, and further including the step of forming at least one or a plurality of indentations or recesses through the profile forming layer to expose a portion or portions of the mask layer.

19. (canceled)

20. Method according to claim 18, further including the step of lithographically defining at least one or a plurality of indentations or recesses in the profile forming layer wherein the lithographically defined at least one or plurality of indentations or recesses are aligned in the <100> or <110> direction of the single crystalline diamond substrate or layer.

21.-22. (canceled)

23. Method according to claim 18, wherein the profile forming layer comprises or consists solely of a photoresist and at least one or a plurality of indentations or recesses are formed through the profile forming layer, to expose at least one portion or portions of the mask layer, by applying a photoresist developer to at least one or a plurality of lithographically exposed indentations or recesses in the profile forming layer.

24. Method according to claim 1, wherein the at least one or the plurality of indentations or recesses comprise or consist solely of grooves or elongated depressions.

25. Method according to the previous claim, further including the step of removing an outer section or outer sections of the profile forming layer so that a central section the profile forming layer remains on the mask layer for forming the at least one indentation or the plurality of indentations in an inner area of the mask layer.

26. (canceled)

27. Method according to claim 1, wherein the single crystalline diamond optical element or is an optical grating or beam splitter element.

28.-31. (canceled)

32. Single crystalline diamond optical element produced according to the method of claim 1 wherein the single crystalline diamond optical element comprises atomically smooth optical surfaces.

33.-35. (canceled)

36. Single crystalline diamond optical element according to claim 32, wherein the single crystalline diamond optical element includes an etched grating optical surface defining an angle α with a planar surface of the single crystalline diamond substrate or layer, where 50°≤α≤65° or 54.7°≤α≤57°.

37.-48. (canceled)

49. Single crystalline diamond optical element, wherein the single crystalline diamond optical element is obtained according to a process comprising the following steps:
providing a single crystalline diamond substrate or layer;
applying a mask layer to the single crystalline diamond substrate or layer;
forming at least one or a plurality of indentations or recesses through the mask layer to expose a portion or portions of the single crystalline diamond substrate or layer; and
reactive ion etching the exposed portion or portions of the single crystalline diamond substrate or layer.
